(19) United States
(12) Patent Application Publication
(10) Pub. No.: US 2006/0220217 A1
(43) Pub. Date: Oct. 5, 2006

(54) High precision connector member and manufacturing method thereof

(75) Inventors: Takushi Yoshida, Tokyo (JP); Seiya Takahashi, Tokyo (JP); Hiroshi Akimoto, Tokyo (JP)

Correspondence Address: WILLIAM COLLARD;COLLARD & ROE, P.C., 1077 NORTHERN BOULEVARD, ROSLYN, NY, 11576, US

(73) Assignee: JAPAN AVIATION ELECTRONICS INDUSTRY, LIMITED

(21) Appl. No.: 11/391,664

(22) Filed: Mar. 28, 2006

(30) Foreign Application Priority Data
Mar. 29, 2005 (JP) 2005-95191

(51) Int. Cl. H01L 23/48

(52) U.S. Cl. 257/692; 257/698; 257/E23.065

(57) ABSTRACT

The connection member has a conductor portion (13) and a dummy pattern portion (15) both formed of a metallic conductor and arranged on a base (11). The conductor portion (13) and the dummy pattern portion (15) are formed by etching. The dummy pattern portion (15) has a positioning portion (21) formed by etching away the metallic conductor. The base (11) has a positioning hole (21) formed by applying laser light having a wavelength of 1500 nm or more to the positioning portion.

This application claims priority to Japanese patent application JP 2005-095191, the disclosure of which is incorporated herein by reference.

### BACKGROUND OF THE INVENTION

The present invention relates to a connection member having a conductor portion arranged on an insulating base, and a manufacturing method thereof.

Japanese Laid-Open Patent Publication (JP-A) No. H10-41636 discloses a manufacturing method of a well-known multilayer printed board having viaholes. The multilayer printed board includes a substrate and an interlayer resin insulator layer provided thereon.

In the first step for manufacturing this multilayer printed board, a reference mark is provided on the substrate. Subsequently, the interlayer resin insulator layer is formed on the substrate. A viahole forming aperture is then formed in the interlayer resin insulator layer with the use of laser light. The laser light is applied while the position of the reference mark is recognized by means of light reflected from or transmitted through the reference mark. A coordinate indicating the position for forming the viahole is computed based on the position of the reference mark on the substrate. Laser light is applied to the position specified based on the computation result to form a viahole forming aperture in the interlayer resin insulator layer.

However, this conventional method involves a problem in that the product accuracy is apt to deteriorate due to processing error or processing tolerance of manufacturing equipment. Moreover, the conventional method additionally requires equipment for recognizing the reference mark and computing equipment for computing the viahole forming position coordinate to determine the coordinate, entailing an enormous equipment cost.

### SUMMARY OF THE INVENTION

It is therefore an object of the present invention to provide a high precision connection member and a manufacturing method thereof.

It is also another object of the present invention to provide a manufacturing method of a connection member in which no processing error or processing tolerance is involved.

According to this invention, there is provided a connection member comprising an insulating base, a conductor portion arranged on the base, and a dummy pattern portion arranged on the base, wherein the conductor portion and the dummy pattern portion are formed by etching a metallic conductor formed on the base, the dummy pattern portion has a positioning portion formed by etching away a part of the metallic conductor, and the base has a positioning hole formed in correspondence with the positioning portion by being irradiated with laser light having a wavelength of 1500 nm or more.

According to this invention, there is provided a connection member comprising an insulating base, a conductor portion arranged on the base, and a pair of dummy pattern portions arranged on the base to be adjacent to each other, the conductor portion and the dummy pattern portions being formed by etching a metallic conductor formed on the base.

According to this invention, there is provided a method of manufacturing a connection member including an insulating base and a conductor portion arranged on the base, the method comprising the steps of, forming a conductor pattern of the metallic conductor on the base, etching the conductor pattern to form the conductor portion and the dummy pattern portion, etching a part of the dummy pattern portion to remove the metallic conductor and thereby form a positioning portion; and irradiating the positioning portion with laser light having a wavelength of 1500 nm or more to form in the base a positioning hole corresponding to the positioning portion.

According to this invention, there is provided a method of manufacturing a connection member including an insulating base and a conductor portion arranged on the base, the method comprising the steps of, forming a conductor pattern of the metallic conductor on the base, etching the conductor pattern to form a pair of dummy pattern portions each of which is adjacent to the conductor portion; and irradiating the dummy pattern portions with laser light having a wavelength of 1500 nm or more to cut the base.

### BRIEF DESCRIPTION OF THE DRAWINGS

FIG. 1 is a perspective view illustrating an embodiment of a connection member according to the present invention;

FIG. 2 is a perspective view for explaining a method of manufacturing the connection member shown in FIG. 1;

FIG. 3 is a partially enlarged perspective view of the connection member shown in FIG. 2;

FIG. 4 is a perspective view illustrating a modification of the connection member shown in FIG. 1;

FIG. 5 is a perspective view illustrating a connection body formed by integrating a plurality of connection members shown in FIG. 1;

FIG. 6 is a partially enlarged perspective view of the connection body shown in FIG. 5;

FIG. 7 is a plan view illustrating positions of laser light during cutting of the connection body shown in FIG. 5;

FIG. 8 is a plan view for explaining the positions of laser light during cutting of the connection body shown in FIG. 5;

FIG. 9 is a plan view for explaining the positions of laser light during cutting of the connection body shown in FIG. 5;

FIG. 10 is a perspective view illustrating a connection member obtained by cutting the connection body shown in FIG. 5; and

FIG. 11 is a side view illustrating an example of a state in which the connection member shown in FIG. 1 is connected to objects to be connected, only the connection member being shown in cross section.

### DESCRIPTION OF THE PREFERRED EMBODIMENTS

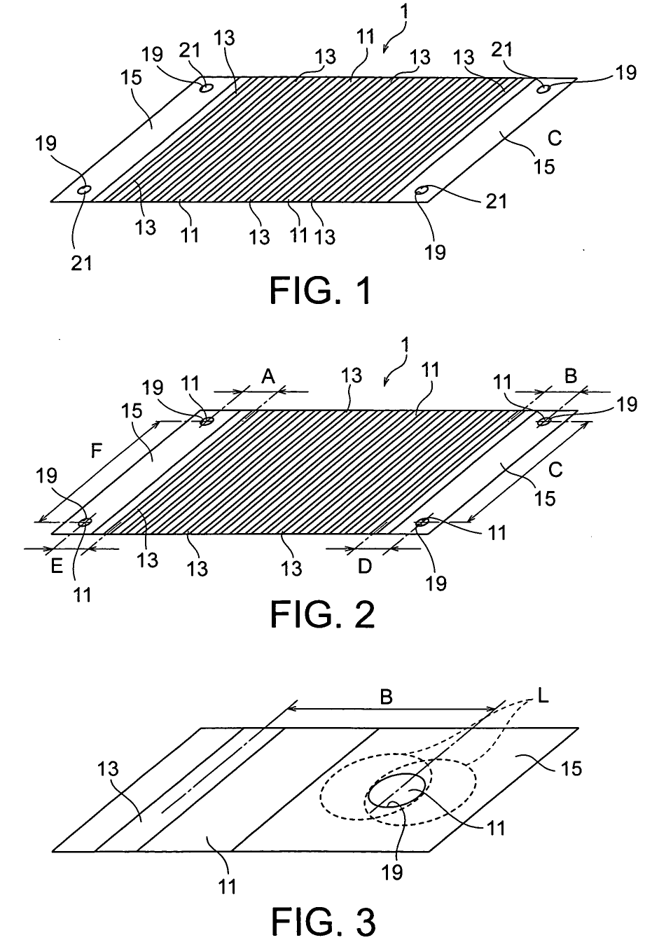

FIG. 1 illustrates an embodiment of a connection member according to the present invention.

Referring to FIG. 1, a connection member 1 includes an insulating base 11 having a rectangular planar shape, a plurality of conductor portions (conductor elements) 13 arranged on one face of the base 11, and a pair of dummy pattern portions 15 arranged on one face of the base 11.

Each of the conductor portions 13 has a strip shape elongated in a second direction intersecting with a first direction, that is, the longitudinal direction of the base 11. The conductor portions 13 are arranged to be spaced from each other in the first direction of the base 11.

The pair of dummy pattern portions 15 are located at the opposite ends in the first direction of the base 11, and have a strip shape elongated in the second direction. The pair of dummy pattern portions 15 are arranged to be spaced from the respective conductor portions 13 present on the outer most sides in the first direction.

The dimension of each dummy pattern portion 15 in the first direction is greater than the dimension of one conductor portion 13 in the first direction. Each of the dummy pattern portions 15 is provided with positioning portions 19 in the vicinity of the opposite ends thereof in the second direction. Each positioning portion 19 has a circular positioning hole 21 formed to pass through the base 11 and the dummy pattern portion 15.

The conductor portions 13 are for electrically connecting between a first object to be connected (not shown) and a second object to be connected (not shown). The dummy pattern portions 15 are dummy portions which are not involved in the connection between the first and second objects to be connected. The positioning portions 19 are for forming positioning holes 21. The positioning holes 21 are used for fastening the first and second objects to be connected when these objects are connected by the connection member 1.

The base 11 is an insulating film. The film is formed from polyethylene terephthalate (PET) resin. The conductor portions 13 and the dummy pattern portions 15 are formed by similar conductive thin films made of a same metallic material. The conductive thin films are formed of a metallic conductor such as gold, copper, nickel, or an alloy thereof.

For the base 11, it is preferable to employ a thin film having a thickness of less than 15 μm so that the base 11 is sensitive enough to laser light to form a hole in the positioning portion 19.

Instead of PET, the base 11 may be formed from a resin selected from among polypropylene (PP) resin, polyethylene naphthalate (PEN) resin, polyimide (PI) resin, and aramid resin.

A manufacturing method of the connection member 1 will now be described with reference to FIGS. 2 and 3. In the first step of the manufacturing method of the connection member 1, a metallic conductor is deposited on one face of the base 11 by plating or vapor deposition. The metallic conductor is then formed by a lithography technology such as photoexposure into a conductor pattern having a shape of a conductor circuit.

The conductor pattern is then etched to form a plurality of conductor portions 13 and a pair of dummy pattern portions 15. During this etching process, the dummy pattern portions 15 are partially etched away to form circular positioning portions 19 in the vicinity of the opposite ends in the second direction.

When the positioning portions 19 are formed, each of the space distances A, B, D, E between the dummy pattern portions 15 and the conductor portions 13 is set to a predetermined dimension to define a range to form a positioning hole 21. Additionally, when the positioning portions 19 are formed, the space intervals C and F in the second direction between the positioning portions 19 on the pair of dummy pattern portions 15 are set to define a range to form the positioning holes 21.

As shown in enlargement in FIG. 3, laser light L is applied to the positioning portion 19 from the side of the dummy pattern portion 15. The laser light L transmitted through the positioning portion 19 forms a hole in the base 11, and thus the positioning hole 21 is provided.

The laser light L has a wavelength of 1500 nm or more within a wavelength range in which the laser light L is reflected by the dummy pattern portion 15 made of a metallic conductor. This reflective wavelength range is determined according to a type of the metallic conductor forming the dummy pattern portion 15.

As shown in FIG. 3, the irradiation diameter of the laser light L applied to the surface of the dummy pattern portion 15 having the positioning portion 19 is set greater than the diameter of the circle of the positioning portion 19. By setting the irradiation diameter of the laser light L in this manner, it is made possible to form a hole in the base 11 with high precision even if the center of the laser light L applied is somewhat offset from the center of the positioning portion 19. This means that the positioning hole 21 can be formed with high precision by irradiating the positioning portion 19 with laser light L having such a wavelength range that is not absorbed by the dummy pattern portion 15 made of a metallic conductor.

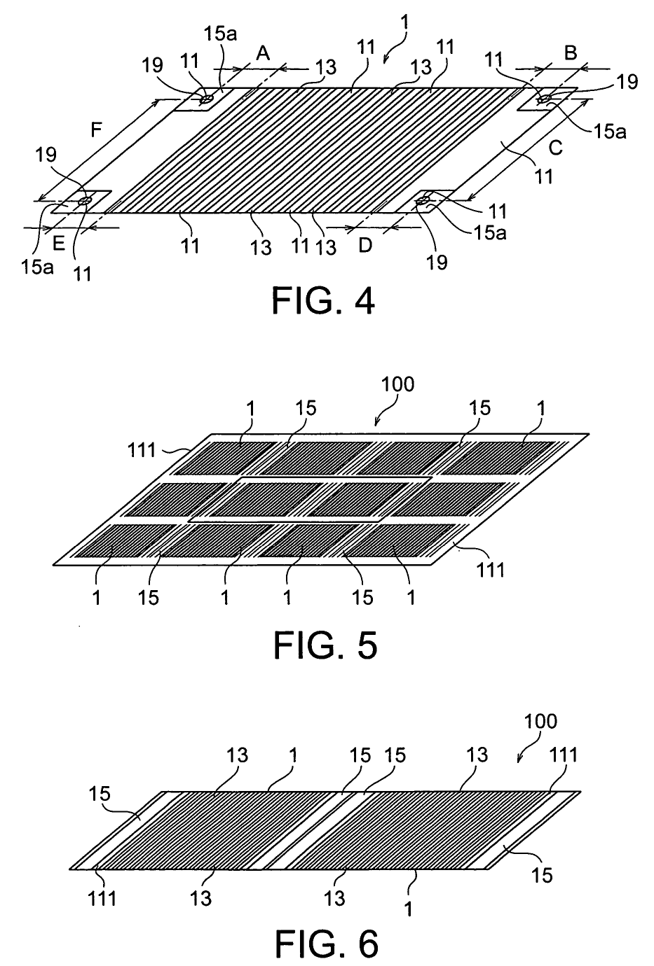

FIG. 4 illustrates a modification of the dummy pattern portion 15 described above with reference to FIGS. 1 and 2, and this modification is different only in the shape.

The base 11 is provided with dummy pattern portions 15a at the four corners in the first and second directions of the base 11. A positioning portion 19 similar to the one shown in FIG. 1 is formed in each of the dummy pattern portions 15a. The structure in other aspects is similar to that described in terms of the connection member 1 with reference to FIGS. 1 and 2.

A similar method to the method of manufacturing the connection member 1 described above with reference to FIGS. 2 and 3 is employed for manufacturing the connection member 1 according to the modification, so that a positioning hole 21 is formed in each of the positioning portions 19.

FIG. 5 shows a connection body 100 in which a plurality of sets of conductive portions and dummy pattern portions are integrally arranged, each set consisting of the conductive portions 13 and dummy pattern portions 15 as shown in FIG. 1. The connection body 100 can be cut off to obtain a connection member 1 as shown in FIG. 1. FIG. 6 is an enlarged view of the connection body 100 shown in FIG. 5, in which two connection members 1 are arranged integrally.

With reference to FIGS. 5 and 6, the connection body 100 has a large-sized base 111 having a rectangular planar shape. The large-sized base 111 includes a plurality of bases 11 integrated together such that the base 111 can be cut and divided into the bases 11 for the connection members 1 shown in FIG. 1. A plurality of sets each consisting of the conductor portions 13 and the dummy pattern portions 15 shown in FIG. 1 are arranged in the first and second directions on the base 111 so that individual connection members 1 can be obtained by cutting the base 111.

As seen from FIG. 5, the base 111 has four sets of the conductor portions 13 and the dummy pattern portions 15 arranged in the first direction and three sets arranged in the second direction, and thus includes twelve sets in total that become individual connection members 1 when the base 111 is cut out.

The dummy pattern portions 15 except those at the opposite ends in the first direction are arranged such that each pair of the dummy pattern portions 15 are adjacent to each other with a space therebetween in the first direction. Each pair of the conductor portions 13 adjacent to each other and each pair of the dummy pattern portions 15 adjacent to each other in the second direction are spaced from each other.

A positioning hole 21 is formed in each positioning portion 19 of each of the dummy pattern portion 15 on the base 111 by a similar method to the manufacturing method as described above with reference to FIGS. 2 and 3.

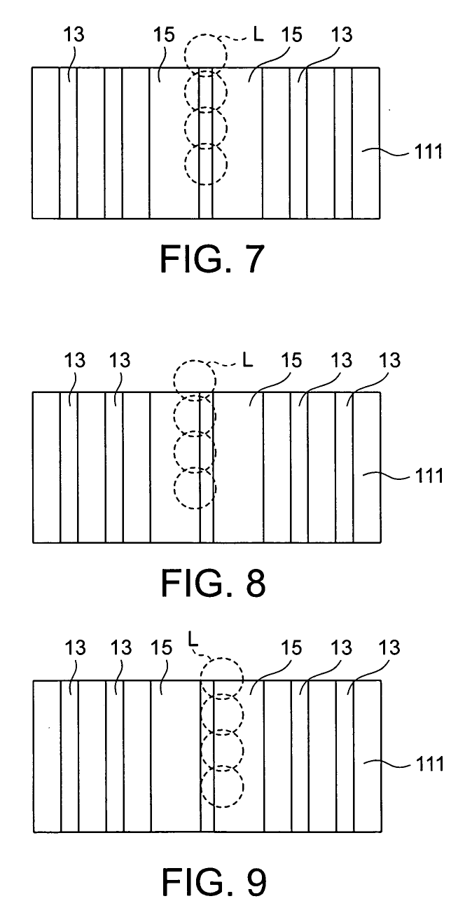

The positioning portions 19 and the positioning holes 21 are not shown FIGS. 5 and 6 or in FIGS. 7 to 9 described below since they are similar to the positioning portions 19 and the positioning holes 21 described with reference to FIGS. 1 and 2.

The base 111 exposed in the space between the adjacent dummy pattern portions 15 is irradiated with laser light L having a wavelength of 1500 nm or more, as shown in the enlarged view of FIG. 7, whereby the base 111 is cut out between the dummy pattern portions 15. The wavelength of the laser light L is set in a wavelength range in which the laser light L is reflected by the dummy pattern portions 15 made of a metallic conductor.

The irradiation diameter L of the laser light L during irradiation is set greater than the distance between the adjacent dummy pattern portions 15. By setting the irradiation diameter L of the laser light L in this manner, it is made possible to cut the base 111 with high precision even if the center of the laser light L is somewhat offset with respect to the base 111 exposed between the dummy pattern portions 15 as shown in FIGS. 8 and 9. The dimension in the first direction of the dummy pattern portion 15 is greater than the dimension in the first direction of the base 111 exposed between the dummy pattern portions 15.

Accordingly, the base 111 can be cut with high precision by being irradiated with the laser light L the wavelength of which is set in such a wavelength range that the laser light L is not absorbed by the dummy pattern portions 15 made of a metallic conductor.

When the base 111 is cut between the dummy pattern portions 15, the distances A1 and B1 in the first direction between the adjacent dummy pattern portions 15 and the conductor portions 13 adjacent to these dummy pattern portions 15 are set to determine the position to be cut between the dummy pattern portions 15. More specifically, each of the distances A1 and B1 is a distance between the outer edge in the first direction of the dummy pattern portion 15 and the conductor portion 13 adjacent to the dummy pattern portion 15.

For cutting and dividing the connection body 100, the laser light is first moved along the second direction to cut the base 111 between the dummy pattern portions 15 and to divide the connection body 100 into four sections. The laser light is then moved along the first direction so that the individual connection members 1 are obtained. Alternatively, the connection body 100 may be cut by moving the laser light first along the first direction to divide the connection body 100 into three sections, and then moving the laser light along the second direction to cut the base 111 between the dummy pattern portions 15 so that the individual connection members 1 are obtained.

Accordingly, the connection body 100 can be cut to define the outline of the individual connection members 1 only by moving the laser light along the first and second directions to cut the connection body 100.

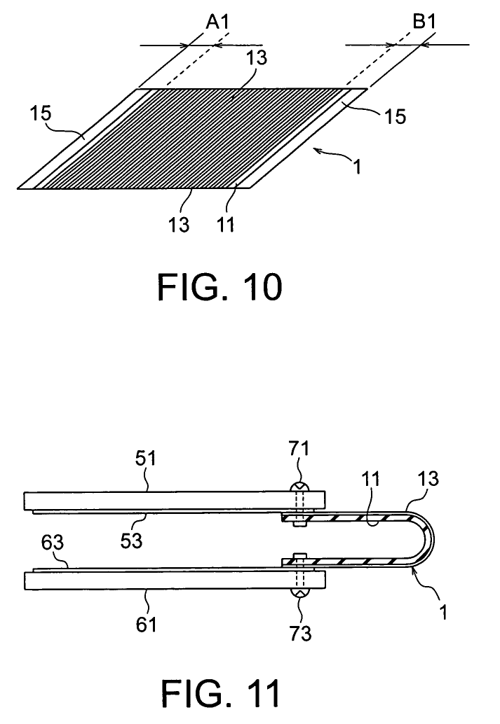

FIG. 10 illustrates one of such connection members 1 obtained by cutting the base 111 between the dummy pattern portions 15 with the use of the laser light L. This connection member 1 is similar to the connection member 1 shown in FIG. 1.

As sown in FIG. 11, the connection member 1 is applicable as a flexible connection member 1 for electrically connecting a first substrate 51 as the first object to be connected and a second substrate 61 as the second object to be connected.

More specifically, the connection member 1 is screw-fastened by inserting a screw 71a into each of a pair of the positioning holes 21 positioned at one side in the second direction of the dummy pattern portion 15 and a through hole (not shown) formed in the first substrate 51. Further, the connection member 1 is screw-fastened by inserting a screw 73 through each of a pair of the positioning holes 21 positioned at the other side in the second direction of the dummy pattern portion 15 and a through hole (not shown) formed in the second substrate 61.

When the connection member 1 is screw-fastened in this manner, one side of each conductor portion 13 in the second direction is abutted against and connected to a conductive pattern 53 on the first substrate 51, while the other side of the conductor portion 13 is abutted against and connected to a conductive pattern 63 on the second substrate 61. The first and second substrates 51 and 61 thus can be electrically connected to each other.

The dummy pattern portions 15 are directly abutted against the surfaces of the first and second substrates 51 and 61 where no conductive pattern 53 or 63 is provided. Alternatively, the dummy pattern portions 15 may be connected to a conductive earth pattern provided on the first and second substrates 51 and 61.

Since the connection member 1 for connecting the first and second substrates 51 and 61 is flexible, it can be used in the state where the base 11 is bent into a substantially U-shape while the first and second substrates 51 and 61 are disposed opposing to each other. When the connection member 1 is used in this state, the dummy pattern portions 15 formed of a metallic conductor and having a dimension in the first direction greater than that of the conductor portions 13 are able to play the role of reinforcement for preventing the deformation of the base 11 when the base 11 is bent into a substantially U-shape.

As described above, the positioning holes 21 are formed by applying laser light L to the positioning portions 19. This makes it possible to improve the dimensional precision of the positioning holes 21 and to achieve highly precise positioning.

Further, the positioning portions 19 can be formed simultaneously when the conductor portions 13 and the dummy pattern portions 15 are formed on the base 11. Still further, no machining work using a press machine is required for forming the positioning holes 21, since they are formed with the laser light L.

Consequently, according to the manufacturing method of the present invention, the connection member of the base 11 will exhibit no deterioration in the dimensional precision of the conductor portions 13, dummy pattern portions 15, and positioning portions 19 caused by accumulation of tolerances due to burrs or the like, and thus no processing tolerance is involved.

Furthermore, no equipment for recognizing images or computing system is required for forming the positioning holes 21. This enables the fabrication of the connection member 1 with high precision.

The connection body 100 is divided by cutting the base 111 between the dummy pattern portion 15 by applying the laser light L thereto. Accordingly, the dimensional precision of the dummy pattern portions 15 can be improved, and highly precise positioning can be achieved.

When the conductor portions 13 and dummy pattern portions 15 are formed on the base 11, the formation of the positioning portions 19 and the cutting of the outlines the connection members 1 are also completed at the same time. Consequently, according to the manufacturing method of the present invention, it is made possible to manufacture, without involving any processing tolerance, the connection members 1 which exhibit no deterioration in dimensional precision of the conductor portions 13, dummy pattern portions 15, and positioning portions 19 caused by accumulation of tolerances due to burrs or the like apt to be produced during the cutting work with a press machine.

According to the embodiment above, the conductor portions 13 and the dummy pattern portions 15 are arranged linearly on the base 11. However, the conductor portions 13 and the dummy pattern portions 15 may be arranged along curved lines. What matters in this respect is that the conductor portions 13 and the dummy pattern portions 15 are arranged on the base 11 with a space therebetween.

The shape of the base 11 is not limited to a rectangular planar shape but may be a circular, elliptical, or square planar shape. The shape of the positioning portion 19 is not limited to circular but may be elliptical or square.

What is claimed is:

1. A connection member comprising:
an insulating base;
a conductor portion arranged on the base; and
a dummy pattern portion arranged on the base, wherein:
the conductor portion and the dummy pattern portion are formed by etching a metallic conductor formed on the base;
the dummy pattern portion has a positioning portion formed by etching away a part of the metallic conductor; and
the base has a positioning hole formed in correspondence with the positioning portion by being irradiated with laser light having a wavelength of 1500 nm or more.

2. The connection member according to claim 1, wherein the conductor portion and the metallic conductor of the dummy pattern portion are formed of a same metallic material.

3. The connection member according to claim 2, wherein the metallic conductor is a conductive thin film.

4. The connection member according to claim 1, wherein the base is an insulating film.

5. The connection member according to claim 4, wherein the insulating film has a thickness of 15 μm or less.

6. The connection member according to claim 1, wherein
the conductor portion has a plurality of conductor elements arranged on the base with a space therebetween in a first direction; and
the dummy pattern portion is arranged on the outside of the outermost one of the conductor elements in the first direction with a space therefrom.

7. The connection member according to claim 6, wherein each of the conductor elements has a strip shape elongated in a second direction intersecting with the first direction.

8. The connection member according to claim 6, wherein the dummy pattern portion has a strip shape elongated in a second direction intersecting with the first direction.

9. The connection member according to claim 6, wherein the dummy pattern portion has a dimension in the first direction that is greater than a dimension in the first direction of the conductor elements.

10. The connection member according to claim 6, wherein
each of the conductor elements assumes a strip shape elongated in a second direction intersecting with the first direction;
the dummy pattern portion has a strip shape elongated in the second direction intersecting with the first direction; and
the dummy pattern portion has a dimension in the first direction that is greater than a dimension in the first direction of the conductor elements.

11. A connection member comprising:
an insulating base;
a conductor portion arranged on the base; and
a pair of dummy pattern portions arranged on the base to be adjacent to each other, the conductor portion and the dummy pattern portions being formed by etching a metallic conductor formed on the base.

12. A method of manufacturing a connection member including an insulating base and a conductor portion arranged on the base, the method comprising the steps of:
forming a conductor pattern of the metallic conductor on the base;
etching the conductor pattern to form the conductor portion and the dummy pattern portion;
etching a part of the dummy pattern portion to remove the metallic conductor and thereby form a positioning portion; and
irradiating the positioning portion with laser light having a wavelength of 1500 nm or more to form in the base a positioning hole corresponding to the positioning portion.

13. A method of manufacturing a connection member including an insulating base and a conductor portion arranged on the base, the method comprising the steps of:
forming a conductor pattern of the metallic conductor on the base;
etching the conductor pattern to form a pair of dummy pattern portions each of which is adjacent to the conductor portion; and
irradiating the dummy pattern portions with laser light having a wavelength of 1500 nm or more to cut the base.

14. The method of manufacturing a connection member according to claim 13, further comprising the steps of:
etching a part of each of the dummy pattern portions to remove the conductor pattern and thereby form a positioning portion; and irradiating the positioning portion with the laser light to form in the base a positioning hole corresponding to the positioning portion.
